(19) United States
(12) Patent Application Publication
(10) Pub. No.: US 2025/0376773 A1
(43) Pub. Date: Dec. 11, 2025

(54) METHODS OF FORMING STABLE CONDUCTIVE SURFACES

(71) Applicant: NORTHWESTERN UNIVERSITY, Evanston, IL (US)

(72) Inventors: Chad A. Mirkin, Wilmette, IL (US); Vinayak P. Dravid, Evanston, IL (US); Carolin B. Wahl, Evanston, IL (US)

(21) Appl. No.: 18/876,553

(22) PCT Filed: Jun. 21, 2023
(86) PCT No.: PCT/US23/25827

§ 371 Date: Dec. 18, 2024

Related U.S. Application Data
(60) Provisional application No. 63/354,100, filed on Jun. 21, 2022.

(51) Int. Cl. C25B 11/053; C23C 14/18; C23C 14/30; C23C 14/58; C25B 11/075

(52) U.S. Cl. CPC C25B 11/053; C23C 14/18; C23C 14/30; C23C 14/5806; C23C 14/5826; C25B 11/075

(57) ABSTRACT

A method of forming a hydrophobic conductive substrate includes forming a metal thin film on a substrate and coating with a hydrophobic coating. For example, the hydrophobic coating can be a self-assembled monolayer of phosphonic acid.

### CROSS-REFERENCE TO RELATED APPLICATION

The benefit of priority to U.S. Provisional Patent Application No. 63/354,100 filed Jun. 21, 2022, is hereby claimed and the disclosure is incorporated herein by reference in its entirety.

### STATEMENT OF GOVERNMENT SUPPORT

This invention was made with government support under grant number ECCS 2025633 AMD 002 awarded by the National Science Foundation and under grant number FA9550-17-1-0348 awarded by the Air Force Office of Scientific Research. The government has certain rights in the invention.

### FIELD

The present disclosure relates to a method of forming a conductive surface, and more particular to a method of forming a conductive surface with tunable hydrophobic properties.

### BACKGROUND

Conductive surfaces have been the subject of recent exploitation for a variety of fields. Such surfaces are typically made of metal, metal oxide, or conductive carbon films. A number of methods for growing metal or metal oxide films, such as atomic layer deposition and physical vapor deposition, yield flat and conductive surfaces. However, these surface are not well-suited for nanoparticle synthesis because the metal surfaces may alloy with the nanoparticle precursors and metal oxides suffer from poor thermal stability in the reducing atmospheres necessary for the synthesis of metallic nanoparticles.

Glass carbon surfaces are better suited for nanoparticle synthesis, but are either insufficiently flat or suffer from cracking or wrinkling of the surface during preparation or under the electrical biases applied in electrocatalytic applications. The hydrophobicity of the glass carbon is also difficult to tune for desired synthesis applications.

### SUMMARY

A method for producing flat, hydrophobic, and conductive substrates is provided herein. The substrates are thermally and electrochemically stable. The substrates are particularly well suited for nanoparticle synthesis.

A method for producing hydrophobic, conductive substrates in accordance with the disclosure can include depositing a conductive metal-containing thin film on a substrate, wherein the conductive metal-containing thin film comprises a metal capable of forming a native oxide on the substrate or is semiconducting and wherein metal-containing thin film is amorphous or crystalline with non-oxygen-terminated facets; and forming a hydrophobic coating on the conductive metal-containing thin film to thereby provide the hydrophobic, conductive substrate, wherein the hydrophobic coating comprises phosphonic acid.

A method for producing hydrophobic, conductive substrates in accordance with the disclosure can include providing a conductive substrate or depositing a conductive metal-containing thin film on a substrate; and forming a hydrophobic coating on the substrate or conductive metal-containing thin film by depositing a plasma polymerized fluorocarbon layer thereon, wherein the plasma polymerized fluorocarbon layer has a thickness of at least 2 nm.

### BRIEF DESCRIPTION OF THE DRAWINGS

FIGS. 1A to 1C are AFM height images of (A) hydrophobic Ti, (B) Ti treated with 100 W argon plasma for 30 min, (C) commercial silicon wafer. Native Ti surfaces were prepared by PVD.

FIG. 2A to 2B are images showing a contact angle measurement of water on (A) Native Ti, which had a contact angle of 55°, and (B) hydrophobic Ti, which had a contact angle of 112°.

FIGS. 3A to 3D are XPS spectra of native Ti showing (A) survey, (B) carbon 1s, (C) oxygen 1s, and (D) titanium 2p. The native surfaces included metallic titanium and several nm of native oxide.

FIGS. 4A to 4F are XPS spectra of native Ti showing (A) survey, (B) carbon 1s, (C) oxygen 1s, (D) titanium 2p, (E) Fluorine 1s, and (F) phosphorous 2p. The hydrophobic surface consisted of metallic titanium and several nm of native oxide as well as phosphorous and fluorinated carbon, expected form surface modification with F₂₁DDPA.

FIGS. 5A to 5D are XPS spectral of a titanium surface cycled repeatedly between −2.2 and 2.45 V vs Ag/AgCl in 0.1 M Na₂SO₄ showing (A) survey, (B) carbon 1 s, (C) oxygen 1s, and (D) titanium 2p. The surface showed no significant changes compared to the native titanium surface, demonstrating the methods of the disclosure produce surfaces with excellent electrochemical stability.

FIGS. 6A to 6C are dark field optical microscope images of large scale nanoreactor patterns produced by scanning probe block copolymer lithography at different magnifications with the scale bars being (A) 5.0 nm, (B) 0.5 mm, and (C) 20 μm. Uniform patterns with high surface coverage were obtained when patterning with polymeric pen arrays on conductive substrate formed in accordance with the disclosure.

FIG. 7 is a backscattered electron image of single gold nanoparticles formed in each patterned nanoreactor of a hydrophobic titanium surface formed in accordance with the disclosure, after annealing at 240° C. for 12 hours in H₂. Scale bar 1 μm. The nanoparticle yield from scanning probe block copolymer lithography was comparable to patterns produced on commercial silicon wafers.

FIG. 8 is a graph showing cyclic voltammetry curves of native titanium and platinum nanoparticles mixed with carbon black, immobilized with a Nafion 117 film on the titanium surface in oxygen saturated 0.1M Na₂SO₄. Currents were normalized to surface areas determined from the underpotential deposition of 0.5 mM Pb(ClO₄)₂ in 0.1 M HClO₄ on the respective surfaces. The native titanium surface was inert over a wide potential range while maintaining electrical contact with deposited nanoparticles through it surface oxide.

### DETAILED DESCRIPTION

A method for producing hydrophobic conductive substrates includes depositing a conductive metal thin film on a substrate, and forming a hydrophobic coating on the metal thin film to thereby form the hydrophobic conductive substrate. The hydrophobic coating is formed of a material having molecules that form covalent bonds through oxygen. The methods of the disclosure can be particularly advantages for forming substrates suitable for subsequent nanoparticle synthesis, as the metal conductive thin film does not react with the precursors used in forming the nanoparticles.

Any metal that is conductive and capable of forming a conductive, native oxide layer, or is semiconducting can be used for forming the thin film. For example, the metal can be Ti, Ta, Al, or Cr. Ti can be particularly useful as a stable metal for electrochemical application. For example, the metal can be a metallic film with an oxide surface that is conductive.

The metal thin film can be deposited by any known thin film deposition methods. For example, the metal thin film can be deposited by physical vapor deposition or atomic layer deposition. The thin film can have a thickness, for example, of about 50 nm to about 500 nm. For example, the thin film can be about 50, 60, 70, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, 390, 400, 410, 420, 430, 440, 450, 460, 470, 480, 490, or 500 nm. It was observed that metal films prepared using plasma-assisted ALD were flatter than those prepared by physical vapor deposition, but the purity of the metallic films prepared by ALD was typically lower than PVD produced films. For example, for Ti films, the reduced purity was not expected to have significant performance impact. Without intending to be bound by theory, it is believed that this is due to the nonstoichiometric Ti oxide impurities in the ALD films remain conductive.

The hydrophobic coating can be formed, for example, by depositing a coating comprising phosphonic acid onto the conductive metal-containing thin film. The phosphonic acid provide the coating material with the molecules that form covalent bonds through oxygen. When using a coating material including phosphonic acid, the metal-containing thin films can be amorphous or crystalline with non-oxygen-terminated facets. For instance, the metal thin film can have a crystal orientation that is <100> but not <001> surfaces of anatase TiO₂. Without intending to be bound by theory, it is believed that since the bond between the phosphonic acid and the metal oxide surface is formed by the oxygen moieties on the phosphonate head group and the metal atoms on the surface, this can only occur when there are under-coordinated metal atoms on the crystal surface. If a given crystal plane is terminated by oxygen atoms, the bond cannot form and the phosphonic acid does not attach to the surface.

The hydrophobic coating can be formed of a self-assembled monolayer. For example, self-assembled monolayers can be formed of phosphonic acid. For example, the phosphonic acid can be one or more of 3,3,4,4,5,5,6,6,7,7,8,8,9,9,10,10,11,11,12,12,12-Heneicosafluorododecyl)phosphonic acid (F21-DDPA), ocatdecylphosphonic acid, and 3,3,4,4,5,5,6,6-Nonafluorohexylphosphonic acid. Surface functionalization can be achieved through self-assembly of phosphonic acids onto the surface in a solvent solution. For example, the solvent can be an alcohol. For example, isopropyl alcohol. The substrate having the metal film deposited thereon can be immersed in the solution of phosphonic acid for a time suitable to allow self-assembly of the phosphonic acids to form the hydrophobic coating. For example, the substrate can be immersed in the phosphonic acid solution for 1 hour. The process can be formed at ambient atmosphere, which can be advantageous as compared to other surface modifiers such as silanes for certain substrates.

The surface hydrophobicity can be tuned by the phosphonic acid used. Altering the functional tail groups on phosphonic acid SAMs allows for the tuning of surface properties, such as hydrophobicity, without changing the conductivity or roughness. For example, instead of F21-DDPA, alkylated phosphonic acids such as ocatdecylphosphonic acid result in reduced hydrophobicity compared to their perfluorinated counterparts. Mixed phosphonic acids, such as 3,3,4,4,5,5,6,6-Nonafluorohexylphosphonic acid, or mixture of several different phosphonic acids can be used to tailor the surface hydrophobicity precisely for desired applications.

Phosphonic acid-functionalized surfaces can also be post-modified to fine-tune the contact angle. For instance, a mild (5 W) oxygen plasma for up to 30 s reduces the contact angle of a F21-DDPA-modified surface from 112° to 81°, consistent with hydrocarbon functional groups. In addition to purely hydrophobic phosphonic acids, phosphonic acids with other functional groups can also be used to impart desired chemical functionality on the surface. Phosphonic acids have been found to have enhanced stability on the surface as a result of their three oxygen linkages.

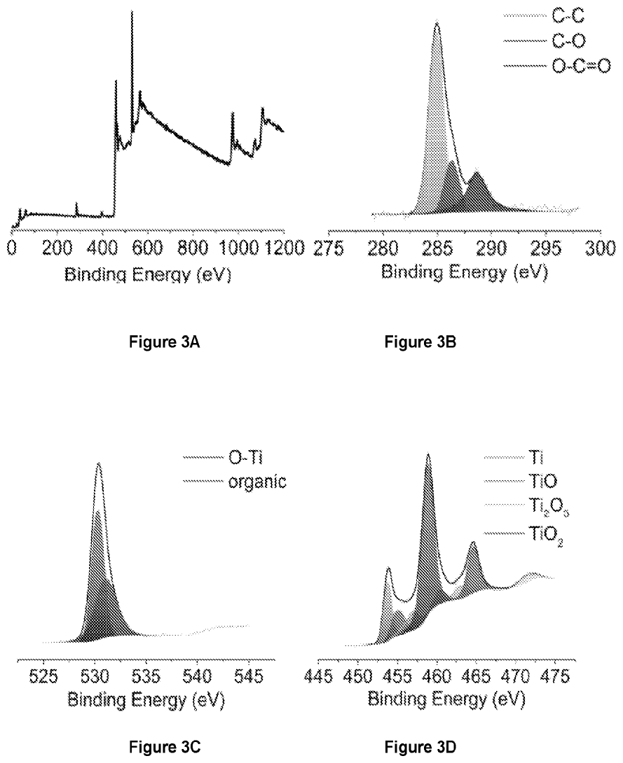

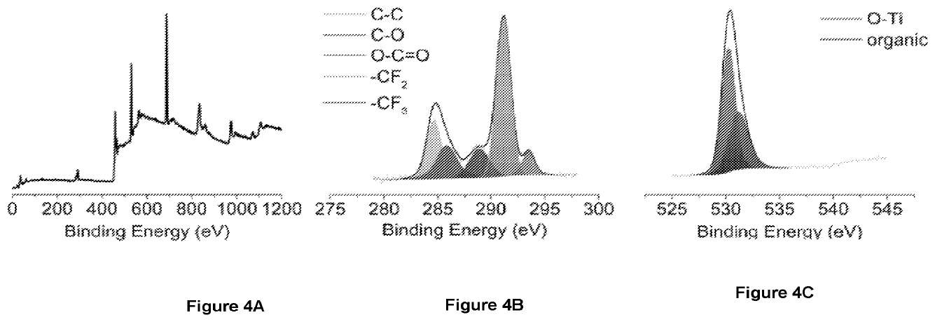

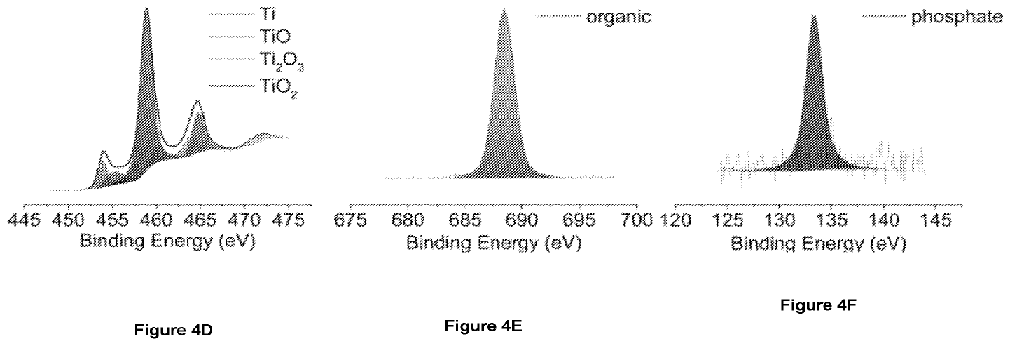

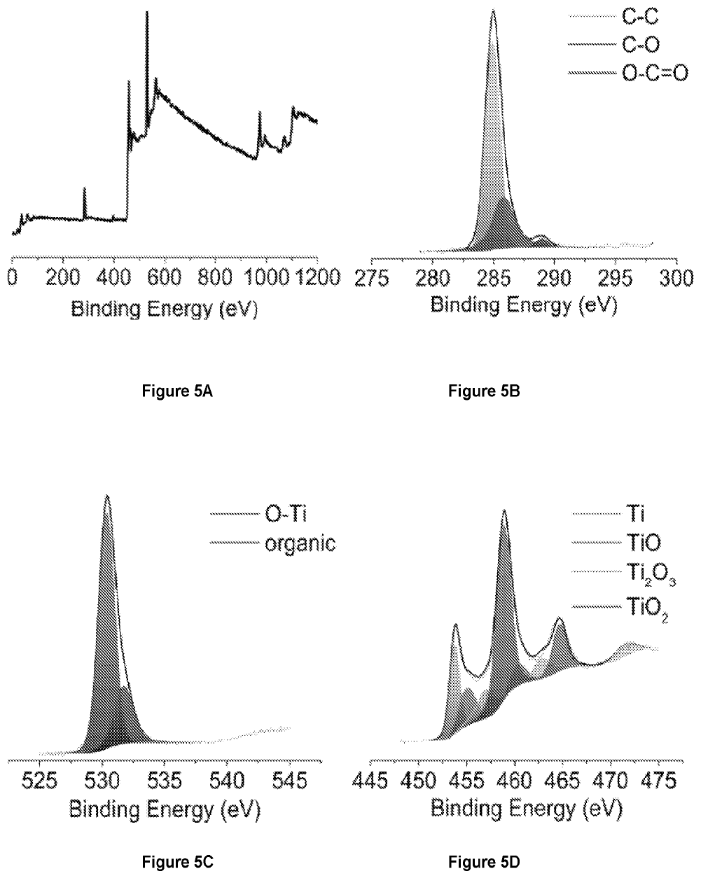

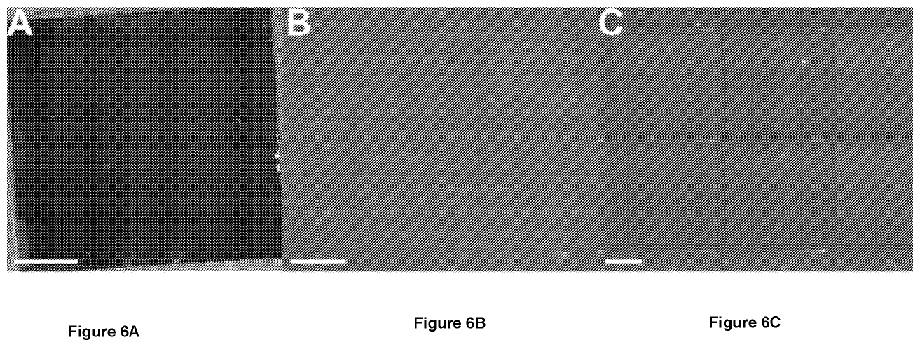

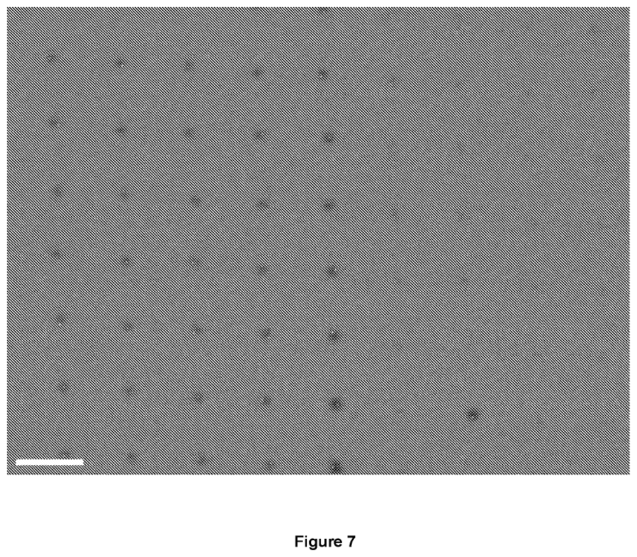

The self-assembled monolayer can be stabilized through annealing. For example, the assembly can be annealed at a temperature of about 100° to about 150° in a protective atmosphere. Annealing can be performed, for example, for about 1 hour. Annealed coatings were observed to be stable in air and water. The surface functionalization can be removed by annealing at temperatures above 200° C. and up to 400° C. or by a potential sweep. FIGS. 3 and 4 shows the XPS spectra of surfaces prepared by this method. The native film shows metallic titanium and its native oxide. After functionalization with F21-DDPA, the spectra show the appearance of its corresponding functional groups that disappear after annealing or potential cycling. The substrates were found to be stable up to at least 600° C. in oxygen-free conditions, including strongly reducing atmospheres such as H₂. The presence of oxygen at high temperatures resulted in a semiconducting titanium oxide film.

Alternatively, the hydrophobic coating can be formed by plasma polymerized fluorocarbons. For example, the coating can include plasma-polymerized C₄F₈, parylene, or plasma-polymerized CHF₃. The plasma polymerized fluorocarbons can be formed by generating a plasma in a chamber containing low pressures of the appropriate gas such as C₄F₈, and any substrate to be coated. The plasma power can for example be 300 W. The duration of the plasma exposure determines the thickness of the fluorocarbon layer or film. Conventionally, plasma polymerized fluorocarbons are not utilized as hydrophobic coatings. The methods of depositing the plasma polymerized hydrophobic coating in accordance with the disclosure can allow for thicker coatings to be deposited on the substrate, making the process capable of producing hydrophobic coatings on a variety of substrates including, but not limited to, conductive substrates, and substrate containing conductive metal-containing thin films. For example, the plasma-polymerization of C₄F₈ is typically used in deep reactive ion etching (DRIE) systems to assist in the dry etching of high aspect ratio vertical features into silicon. In that process, very thin films are generated at intermediate stages to serve as temporary protective layers during plasma cycles. Here, this capability is adapted to be used for thicker film deposition of films that remain on the surface to provide hydrophobicity. Any thickness greater than about 2 nm was observed to be suitable as a hydrophobic coating. There was no upper limit on the film thickness observed that affects its hydrophobic properties. Suitable film thicknesses can be determined depending on whether certain properties of the underlying surface are required for a particular application of the coating. For instance, if the underlying surface is conductive, the plasma-polymerized film can be about 2 nm to about 20 nm in order to maintain the conductivity of the surface through the hydrophobic coating.

The hydrophobic coating can be selected to be compatible with masked surfaces that can be used to fabricate arbitrary hydrophobic patterns on the substrate surfaces.

Any suitable substrate can be used. For example, the substrate can be conductive. For example, silicon can be used as a conductive substrate. For example, the substrate can be doped silicon. Such substrates after coating can be conductive all the way through. An insulating substrate could alternatively be used. For example, sapphire can be used as an insulating substrate. When using an insulating substrate, the resulting substrate with the metal and hydrophobic coating is conductive on one side (the coated side) and insulating on the other. Any known substrate cleaning processes can be used prior to depositing the metal thin film. For example, native silicon oxide can be removed from silicon wafers prior to deposition.

The method of the disclosure can further include annealing the substrate after forming the hydrophobic coating. For example, annealing can be performed a temperature below a decomposition temperature of the hydrophobic coating. For example, the hydrophobic coatings can be annealed at an annealing temperature at or below 400° C. At temperatures above 400° C. it was observed that the hydrophobic coating degrades. Such high temperatures can be used to remove the hydrophobic coating, if desired. For example, the coating can be removed by heating the substrate with the coating to a temperature of about 700° C.

The resulting conductive substrate can be substantially flat. Flat, hydrophobic, conductive substrates can be particularly advantageous for use in patterning preparing nanoparticles arrays. Downstream electrochemical screening can be performed by patterning nanoparticle arrays on such surfaces when they are sufficiently inert and stable in the desired potential ranges.

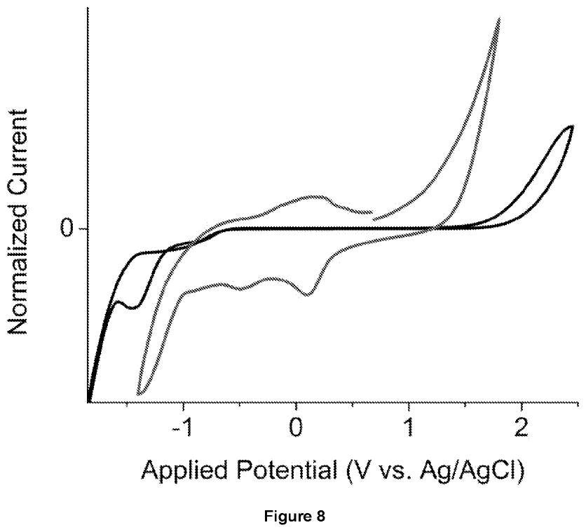

The substrates formed by methods of the disclosure were found to be inert and stable in a significantly wider potential window than glassy carbon, shown in FIG. 8. This makes them particularly suited for electrochemical reactions such as oxygen evolution and carbon dioxide reduction that occur at extreme potentials. The substrates also maintained electrical contact with materials on their surface, making them suitable for use as electrodes.

### Example

A 100 nm film of Ti was evaporated onto a doped silicon wafer using a Kurt J. Lesker PVD 75 Pro-Line E-beam evaporator. To generate a hydrophobic surface, the wafer was submerged in a 2.0 mM solution of F21-DDPA in isopropanol for one hour, rinsed with isopropanol and then annealed at 120° C. in Ar for one hour.

Scanning probe block copolymer lithography was performed on a TeraFab M-series polymer pen lithography system (Tera Print LLC), using custom uncoated pen arrays derived from previously reported procedures (Huo, F. et al., Science 321, 1658-1660 (2008).; Eichelsdoerfer, D. et al. Nat Protoc 8, 2548-2560 (2013)). Patterns were annealed at 240° C. in H2 for 12 hours to produce nanoparticle arrays.

AFM characterization was performed on a Bruker Dimension Icon atomic force microscope in standard tapping mode. Contact angles were measured on a Rame-Hart contact angle goniometer. XPS measurements were performed using a Thermo Fisher ESCALAB Xi X-ray photoelectron spectrometer equipped with an Al Ka source; charge compensation during measurements was employed. The binding energies were calibrated to adventitious carbon at 284.8 eV. The peaks were fitted with Gaussian-Lorentzian product functions using Thermo Fisher Avantage software. Optical images were obtained on a Zeiss AXIO optical microscope. SEM imaging was performed using a JEOL JSM-7900FLV scanning electron microscope operated at 5 kV using a backscattered electron detector. Electrochemical characterization was performed using a Metrohm Autolab potentiostat.

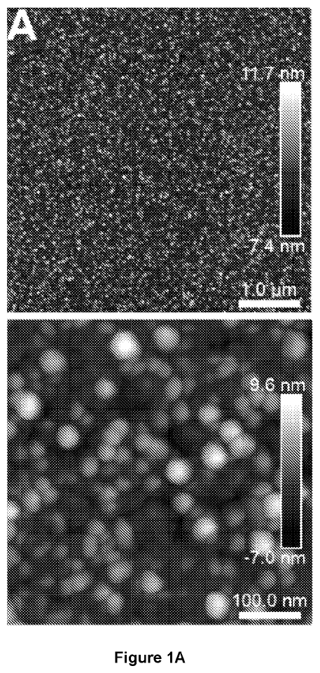

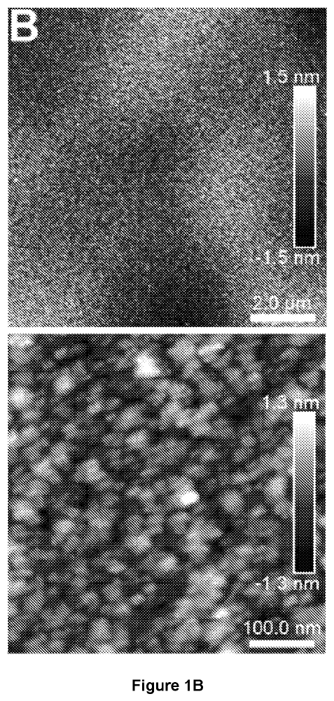

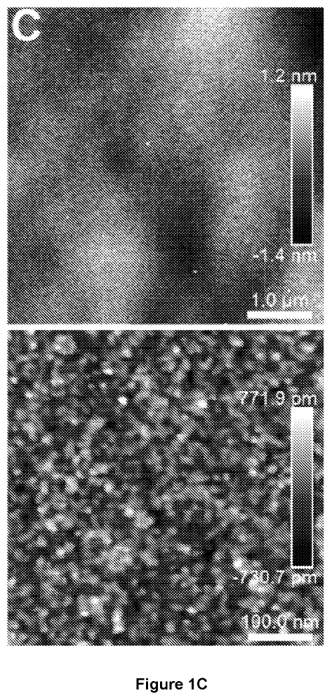

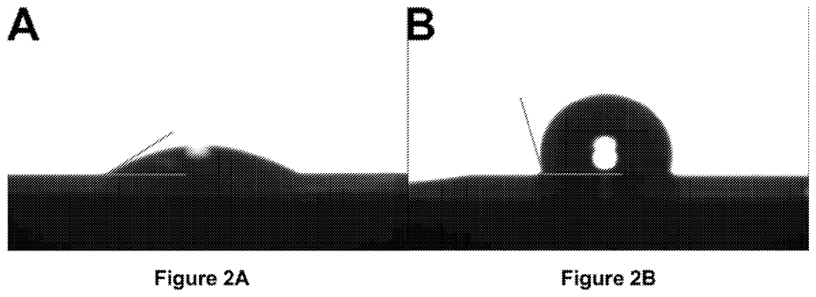

FIG. 1 shows the resulting surface, which was found to be flat over large areas. FIG. 2B shows the greatly increased hydrophobicity compared to the native surface in FIG. 2A. Advantageously, the method of the disclosure is compatible with large-scale fabrication and can be applied directly to 100 mm diameter wafers. It is limited only by the size of the available PVD system.

The technical information set out herein may in some respects go beyond the disclosure of the invention, which is defined exclusively by the appended claims. The additional technical information is provided to place the actual invention in a broader technical context and to illustrate possible related technical developments. Such additional technical information which does not fall within the scope of the appended claims, is not part of the invention.

While particular embodiments of the present invention have been shown and described in detail, it will be obvious to those skilled in the art that changes and modifications may be made without departing from the invention in its broader aspects. Therefore, the aim is to cover all such changes and modifications as fall within the true spirit and scope of the invention. The matters set forth in the foregoing description and accompanying drawings are offered by way of illustration only and not as limitations. The actual scope of the invention is to be defined by the subsequent claims when viewed in their proper perspective based on the prior art.

What is claimed is:

1. A method for producing hydrophobic, conductive substrates, comprising:
depositing a conductive metal-containing thin film on a substrate, wherein the conductive metal-containing thin film comprises a metal capable of forming a native oxide on the substrate or is semiconducting and wherein metal-containing thin film is amorphous or crystalline with non-oxygen-terminated facets; and
forming a hydrophobic coating on the conductive metal-containing thin film to thereby provide the hydrophobic, conductive substrate, wherein the hydrophobic coating comprises phosphonic acid.

2. The method of claim 1, wherein the hydrophobic coating is a self-assembled monolayer.

3. The method of claim 1, wherein the phosphonic acid is one or more of 3,3,4,4,5,5,6,6,7,7,8,8,9,9,10,10,11,11,12,12,12-heneicosafluorododecyl)phosphonic acid (F21-DDPA), ocatdecylphosphonic acid, and 3,3,4,4,5,5,6,6-nonafluorohexylphosphonic acid.

4. A method for producing hydrophobic, conductive substrates, comprising:
providing a conductive substrate or depositing a conductive metal-containing thin film on a substrate; and
forming a hydrophobic coating on the substrate or conductive metal-containing thin film by depositing a plasma polymerized fluorocarbon layer thereon, wherein the plasma polymerized fluorocarbon layer has a thickness of at least 2 nm.

5. The method of any one of claims 1 to 4, wherein the substrate is conductive.

6. The method of claim 5, wherein the conductive substrate is a silicon.

7. The method of claim 1, wherein the substrate is insulating.

8. The method of claim 4, comprising depositing the conductive metal-containing thin film on an insulating substrate.

9. The method of claim 7 or 8, wherein the insulting substrate is sapphire.

10. The method of claim 4, wherein the hydrophobic coating comprises plasma-polymerized C₄F₈, parylene, or plasma-polymerized CHF₃.

11. The method of any one of the preceding claims, wherein the conductive metal-containing thin film is deposited by physical vapor deposition or atomic layer deposition.

12. The method of any one of the preceding claims, wherein the conductive metal-containing thin film comprises one or more of Ti, Ta, Al, and Cr.

13. The method of any one of the preceding claims, wherein a metal of the conducting metal-containing thin film is semiconducting and/or adapted to form conductive native oxides.

14. The method of any one of the preceding claims, further comprising annealing the substrate after forming the hydrophobic coating.

15. The method of claim 14, wherein annealing is performed at an annealing temperature of less than 400° C.

16. The method of any one of the preceding claims, wherein the substrate is flat.
